(19) United States
(12) Patent Application Publication
(10) Pub. No.: US 2007/0166924 A1
(43) Pub. Date: Jul. 19, 2007

(54) Memory cell and method for fabricating a memory device

(75) Inventors: Michael Kund, Tuntenhausen (DE); Thomas Mikolajick, Dresden (DE); Cay-Uwe Pinnow, Corbell-Essonnes (FR)

Correspondence Address: DICKE, BILLIG & CZAJA, FIFTH STREET TOWERS, 100 SOUTH FIFTH STREET, SUITE 2200, MINNEAPOLIS, MN, 55402, US

(73) Assignee: INFINEON TECHNOLOGIES AG, Munchen (DE)

(21) Appl. No.: 10/565,578

(22) PCT Filed: Jul. 21, 2004
(86) PCT No.: PCT/DE04/01588

§ 371 Date: Aug. 14, 2006

(30) Foreign Application Priority Data
Jul. 23, 2003 (DE) 103 33 557.9

(51) Int. Cl. H01L 21/336

(52) U.S. Cl. 438/266

(57) ABSTRACT

When fabricating a memory cell with an organic storage layer which stores a digital information item, processing of polycrystalline and monocrystalline semiconductor structures in which high temperatures are employed is concluded prior to application of the organic storage layer.

### BACKGROUND

The invention relates to a method for fabricating a memory device, which includes semiconductor structures, with memory cells, in which digital information is stored in a storage layer. Two source/drain regions, which are spaced apart from one another by a channel region, are formed in a semiconductor substrate, and a gate dielectric is provided on a substrate surface of the semiconductor substrate, substantially above the channel region.

The invention relates to a memory cell having a storage layer that stores a digital information item, having two source/drain regions, which are formed in a semiconductor substrate and are spaced apart from one another by a channel region, and a gate dielectric, which is provided on a substrate surface of the semiconductor substrate, substantially above the channel region.

Memory cells, in which digital information is stored as a charge state of a charge-storing unit, are used to fabricate DRAM (dynamic random access memory) or EEPROM (electrically erasable and programmable read-only memory) memory devices. To enable the charge state of the charge-storing unit in the memory cell to be reliably measured, the quantity of stored charge must not drop below a predetermined minimum. This fact entails considerable outlay when further reducing the size of the memory cells, since the smaller the memory cell becomes, so too the lower the possible quantity of stored charge will be and the more complex it will be to reliably detect the charge state of the cell.

One approach aimed at improving the situation consists in designing the charge-storing unit of a memory cell, which is usually designed as a capacitor connected to a select transistor, as a storage layer which stores charge and is arranged above the channel region of a field-effect transistor. As a result, the charge stored in the storage layer can be capacitively introduced into the channel region of the field-effect transistor, thereby utilizing an amplification of the field-effect transistor. On account of the amplification of the field-effect transistor, just a small quantity of stored charge is sufficient to allow reliable detection of the stored information. This approach is used, for example, for ferroelectric field-effect transistors, in which the storage layer consists of a ferroelectric material. A detailed description of a field-effect transistor with ferroelectric storage layer is to be found in the publication by I. Ishiwara, Recent Progress of FET-Type Ferroelectric Memories, Integrated Ferroelectrics 34 (2001), 11-20.

If the storage layer consists of an organic material, it is customary for the organic storage layer, on account of the small quantity of stored charge, in accordance with the approach described above to be arranged directly above the channel region of a field-effect transistor, so that the amplification of the field-effect transistor can be utilized. The organic storage layer may consist, for example, of porphyrin molecules. Oxidation and reduction of the porphyrin molecules lead to different charge states in the storage layer. A reduction corresponds to the storage layer being charged with electrons, and an oxidation corresponds to the storage layer being discharged. To determine the charging state of the storage layer, which represents the digital information, a constant read voltage is applied to a gate electrode of the field-effect transistor, and a resulting drain current between the two source/drain regions is detected. If the storage layer is charged with electrons, a threshold voltage, above which the drain current is approximately exponentially dependent on the level of the gate voltage, shifts toward higher voltage values. If a suitable read voltage is used, the drain current is approximately nonexistent in the reduced state of the storage layer and characterizes a logic state of zero. In the oxidized state of the storage layer, a drain current flows and characterizes a logic state one.

A conventional field-effect transistor of a memory cell with an organic storage layer is illustrated in FIG. 1. Two source/drain regions 5 are separated from one another by a channel region 4 in a semiconductor substrate. On the channel region 4 there is a gate dielectric 6, and on the gate dielectric 6 there is an organic storage layer 10. A gate electrode 7 is provided on the organic storage layer 10.

A predetermined read voltage is applied to the gate electrode 7, and when this read voltage is applied, a drain current or virtually no drain current flows between the two source/drain regions 5 depending on whether the storage layer 10 is in a reduced state or an oxidized state.

The way in which the drain current is dependent on the charge state of the storage layer as described is illustrated in FIG. 5. The logarithm of the drain current is plotted on the ordinate, and the gate voltage of an n-channel field-effect transistor, containing an organic storage layer, of a memory cell as illustrated in FIG. 1 is plotted on the abscissa. A memory cell of this type can also be implemented without restriction using a p-channel field-effect transistor. The current/voltage characteristic curve indicated by a corresponds to the field-effect transistor with a discharged, oxidized storage layer. The current/voltage characteristic curve denoted by b corresponds to the field-effect transistor with a charged, reduced storage layer. Oxidization or reduction of the organic layer leads to a parallel shift in the current/voltage characteristic curve of the field-effect transistor along the abscissa. The value U_{L} marked on the abscissa indicates the level of the read voltage at the gate electrode. If the storage layer of the field-effect transistor is in a reduced state with the current/voltage characteristic curve b, the drain current D₂ on the ordinate associated with the value UL is virtually zero. If the storage layer is in oxidized state with the current/voltage characteristic curve a, the drain current D1 associated with the value UL adopts a significantly higher value. It is therefore possible to distinguish between two charge states of the storage layer with a constant read voltage at the gate electrode, on the basis of the level of the resulting drain current.

However, there are disadvantages associated with the fabrication of memory devices having the memory cells illustrated in FIG. 1. In a conventional method for fabricating memory devices, semiconductor structures of the field-effect transistors of memory cells and their insulation with respect to one another are processed first of all. This concludes a part of the overall process which is also referred to as the FEOL (front end of line) and involves the processing of monocrystalline and polycrystalline semiconductor structures. Processing of the semiconductor structures is followed by contact-making and connection of the individual monocrystalline and polycrystalline semiconductor structures. This part of the overall process is also known as the BEOL (back end of line). Since very high temperatures of up to 1100 degrees Celsius are used in the FEOL, the conventional memory cell with field-effect transistor with an organic storage layer which is arranged on the gate dielectric beneath the polycrystalline gate electrode as illustrated in FIG. 1 is very difficult to implement, since in most cases, organic storage layers are very temperature-sensitive, and arranging them beneath the gate electrode requires the storage layer to be applied in the FEOL section, in which the storage layer is exposed to very high temperatures.

However, if extremely thin insulator layers are used, organic storage layers have the advantage over inorganic storage layers of permanent charge storage. Moreover, organic storage layers have good scaleability. This is advantageous for further reduction of the size of memory cells.

### SUMMARY

One embodiment of the invention provides a method for fabricating a memory device with memory cells in which digital information is stored in a temperature-sensitive storage layer. One embodiment of the invention also provides a memory cell having a temperature-sensitive storage layer.

One embodiment of the invention provides a method for fabricating a memory device, which includes semiconductor structures, with memory cells in which digital information is stored in a storage layer. In the method, two source/drain regions, which are spaced apart from one another by a channel region, are formed in a semiconductor substrate. A gate dielectric is provided on a substrate surface of the semiconductor substrate, substantially above the channel region. A first gate electrode is arranged on the gate dielectric. Processing of the semiconductor structures is concluded before the storage layer is applied. A conductive connection is provided between the storage layer and the first gate electrode. An insulator layer is provided above the storage layer, and a second gate electrode is provided on the insulator layer.

In the method according to one embodiment of the invention, the processing of polycrystalline and monocrystalline semiconductor structures, in which high temperatures are employed, is concluded prior to the application of the storage layer. Examples of polycrystalline or monocrystalline semiconductor structures include source/drain regions, channel region and first gate electrode of a field-effect transistor. Therefore, the application of the storage layer is shifted into a part of the processing in which contact-making and connecting of the individual monocrystalline and polycrystalline semiconductor structures takes place and in which high temperatures are no longer employed. Shifting the application of the storage layer into a later part of the processing generally also requires the storage layer to be separated from the first gate electrode, which is generally formed from a polycrystalline semiconductor substrate. Therefore, a conductive connection is provided between the storage layer and the first gate electrode, for example in the form of a metal-filled contact hole which is introduced into an insulation layer. The second gate electrode, which is separated by an insulator layer from the storage layer, which is conductively connected to the first gate electrode of the field-effect transistor, is used to drive the field-effect transistor.

With the method according to one embodiment of the invention, the thermal stressing of the storage layer is significantly reduced in a simple way and without the need for additional process steps by shifting the application of the storage layer into a later part of the processing. This considerably widens the range of materials which are envisaged for storage layers. The method according to one embodiment of the invention makes it possible to use even organic storage layers.

In one embodiment the storage layer is arranged between a first and a second electrode. As a result of additionally formed electrodes being provided, it is possible to use electrode materials which are suitably adapted to a material of the storage layer. As such, the electrode surfaces can be selected independently of the transistor and contact surfaces.

In one embodiment the first electrode is formed by a portion of the conductive connection. If the conductive connection is formed, for example, as a contact hole filled with a conductive material, it is also possible for the storage layer to be applied direct to the contact hole filling. This allows one process step to be saved.

In one embodiment the metals aluminium, tungsten or copper are provided for the first and second electrodes. These are metals which are also used in the other process steps. Therefore, forming the electrodes would not require an additional process step.

In one embodiment one of the precious metals platinum, gold or silver is provided for the first and second electrodes.

In one embodiment the first electrode is formed in a first metal level and the second electrode to be formed in a second metal level. The conductive connection between the first gate electrode and the first electrode is produced by a contact hole filled with conductive material.

Forming the first and second electrodes in respective metal levels means that there is no need for an additional process step for forming the electrodes, since the electrodes can be processed together with interconnects which are formed in the metal levels. In addition, the storage layer can easily be introduced into a hole which is provided in an insulation layer which electrically separates the two metal levels from one another. The conductive connection between the first gate electrode and the first electrode is produced by a contact hole filled with conductive material. There is a further insulation layer between the first metal level and the first gate electrode. Contact holes are introduced into this insulation layer to produce conductive connections to the first metal level. There is no need for an additional process step to produce the contact hole for the conductive connection between the first gate electrode and the first electrode.

In one embodiment the first and second electrodes each are formed in a metal level which is in each case processed later in the process sequence. The conductive connection between the first electrode and the first gate electrode is produced by contact holes arranged above one another and filled with conductive material. As a result of the electrodes being formed at a point in time which comes later in the overall process sequence, that is, as a result of the first and second electrodes being shifted to higher metal levels, the thermal stressing to which the storage layer is exposed is reduced further. The conductive connection between the first gate electrode and the first electrode is produced by contact holes which are arranged above one another and are introduced into the insulation layers between the metal levels. The contact holes which are arranged above one another and are filled with conductive material produce a conductive connection through a plurality of metal levels.

In one embodiment the storage layer provided is an organic layer which may be provided, for example, having porphyrin molecules. Organic storage layers, such as for example those which consist of porphyrin molecules, have permanent charge storage and low leakage currents. The gate dielectric, through which the charge carriers can flow out, can be made thinner than if inorganic storage layers are used. A thinner gate dielectric offers accelerated charging and discharging of the storage layer and therefore faster access times. Moreover, organic storage layers have good scaleability. This is beneficial for a further reduction in the size of memory cells.

To produce source and drain lines, the source/drain regions of memory cells arranged in rows which are respectively adjacent within a row are electrically conductively connected to one another by doped regions provided in the semiconductor substrate. After a predetermined number of source/drain regions which have been electrically conductively connected to one another by doped regions in the semiconductor substrate, conductive connections to interconnects, which are formed in a metal level and connect the source/drain regions of memory cells, are provided. The doped regions can be introduced into the semiconductor substrate by a dopant diffusing in. It is possible to avoid an increase in the surface area taken up by the memory cell on a semiconductor wafer. Maintaining minimum distances between contacts to the metal level and electrodes, between which the storage layer is arranged, would lead to an increase in the surface area taken up by the memory cell. The provision of lines which are formed as doped regions in the semiconductor substrate allows contacts to the metal level to be provided after a predetermined number of memory cells, and consequently there is no longer any need to provide a contact to the metal level in each memory cell.

In one embodiment, a memory cell is provided having a storage layer, which stores a digital information item, having two source/drain regions, which are formed in a semiconductor substrate and are spaced apart from one another by a channel region, and having a gate dielectric which is arranged on a substrate surface of the semiconductor substrate, substantially above the channel region. According to one embodiment of the invention, a first gate electrode is arranged on the gate dielectric. The storage layer is arranged on the first gate electrode or at a distance from the first gate electrode. There is a conductive connection between the storage layer and the first gate electrode. An insulator layer is provided above the storage layer, and a second gate electrode is provided on the insulator layer.

The memory cell according to one embodiment of the invention has monocrystalline and polycrystalline semiconductor structures, such as for example channel region, source/drain region and first gate electrode of a field-effect transistor, that can be processed prior to the application of the storage layer. Since high temperatures are usually employed during the processing of semiconductor structures, the application of the storage layer at a later time reduces the thermal stressing of the storage layer. This prevents degradation of, for example, organic storage layers. The storage layer is charged and discharged as a result of the conductive connection of the storage layer to the first gate electrode. The memory cell according to one embodiment of the invention allows the range of materials which can be used to form the storage layers to be widened considerably.

The storage layer is arranged between a first and a second electrode. The provision of additionally formed electrodes makes it possible to use electrode materials which are suitably adapted to a material of the storage layer. The electrode surfaces can be selected independently of the transistor and contact surfaces.

In one embodiment the first electrode to be formed by a portion of the conductive connection. For example, if the conductive connection is designed as a contact hole filled with a conductive material, it is also possible for the storage layer to be applied direct to the contact hole filling, allowing one process step to be saved.

In one embodiment the first and second electrodes consist of one of the metals aluminium, tungsten or copper. These are metals which are also used in the other process steps. Therefore, forming the electrodes would not require an additional process step.

In one embodiment the first and second electrodes consist of one of the precious metals platinum, gold or silver.

In one embodiment the first electrode is formed in a first metal level and the second electrode to be formed in a second metal level. The conductive connection between the first gate electrode and the first electrode is provided by a contact hole filled with conductive material. Forming the electrodes, between which the storage layer is arranged, in adjacent metal levels containing interconnects and contact holes avoids additional process steps for forming the electrodes. If the conductive connection is produced by a contact hole which is filled with conductive material and has been introduced into an insulation layer arranged between the first gate electrode and the first metal level, there is no need for any additional process steps.

The first and second electrodes are each formed in a metal level which is in each case further away from the first gate electrode than the first or the second metal level. The conductive connection between the first electrode and the first gate electrode is provided by contact holes which have been introduced into insulation layers, are arranged above one another and have been filled with conductive material. Arranging the electrodes in metal levels located higher than the first or second metal level further reduces the thermal stressing of the storage layer. The conductive connection between the first gate electrode and the first electrode is provided by contact holes which are arranged above one another and produce a connection through a plurality of metal levels.

The storage layer is provided in the form of an organic layer which, for example, contains porphyrin molecules. Such layers permanently bond charge carriers and have predominantly low leakage currents. The gate dielectric, through which the charge carriers can flow out, can be made thinner. A thinner gate dielectric offers accelerated charging and discharging of the storage layer. Moreover, organic storage layers have good scalability. This further reduces the size of memory cells.

A memory device is provided having memory cells which are arranged in rows, include semiconductor structures and store a digital information item. The memory cells according to one embodiment of the invention are arranged in the memory device. The memory device has the feature that digital information can be stored in it in organic storage layers. On account of the permanent nature of the charge storage, leakage currents are reduced. Memory devices having the memory cells according to one embodiment of the invention are distinguished by permanent information storage and accelerated programming operations.

To provide source and drain lines, source/drain regions of memory cells which are respectively adjacent in a row are electrically conductively connected to one another by doped regions provided in the semiconductor substrate. After a predetermined number of source/drain regions which have been electrically conductively connected to one another by doped regions in the semiconductor substrate, conductive connections to interconnects, which are formed in a metal level and connect the source/drain regions of memory cells, are provided. Source and drain lines which are locally diffused with a dopant in a semiconductor substrate save surface area on a semiconductor wafer for each memory cell on account of the fact that there is no need for each individual memory cell to be contact-connected to the metal level. On the other hand, lines which consist of doped semiconductor substrate have a higher resistance. To compensate for this higher resistance, a conductive connection to the interconnect in the metal level is provided after a predetermined number of memory cells, for example eight or sixteen memory cells. This compensates for an increased resistance yet nevertheless utilizes the saved surface area.

In a method for operating one embodiment of the memory device, to program the memory device the respective storage layers of selected memory cells are charged. This is done by applying voltages to the source/drain regions contained in the selected memory cells and the second gate electrode. The storage layers are then charged by means of high-energy electrons or by means of an electron tunnelling operation through the gate dielectric. To erase the programming, the charged storage layers are discharged by means of an electron tunnelling operation to the channel region or to a source/drain region as a result of an erase voltage, which differs from the voltage applied during programming, being applied to the second gate electrode. To read the programmed memory device, the strength of a drain current is detected as a function of a charge state of the storage layer.

A voltage between the second electrode and the channel region which is high enough for at least a reduction potential suitable for the storage layer to be present at the storage layer is required to charge the storage layer in the memory cell. The required voltage can be generated by applying a positive potential to the second electrode and a negative potential to a doped region in the semiconductor substrate in which source/drain regions and channel region of a transistor are formed and which is also referred to as the well. If the voltage at the second gate electrode is sufficient to effect charging of the organic storage layer, it is also possible to apply a voltage to the drain region. If the material used for the storage layer has a plurality of redox states, it is possible to write a plurality of states by applying various voltages. Accordingly, to erase the charged storage layer, it is possible to apply the oxidation potentials, that is, a negative potential is applied to the second electrode and a positive potential is applied to the well.

To charge the storage layer in the memory cell, by way of example, a voltage of 5 V to 7 V can be applied to the drain region and a voltage of 10 V to 12 V can be applied to the second gate electrode. Under these voltage conditions, high-energy electrons are generated in the channel region of the field-effect transistor, and these electrons pass through the gate dielectric into the first gate electrode and through the conductive connection to the storage layer. Electrons are received and retained by the storage layer. A change in the charge state and therefore also a change in the electrical potential has occurred in the storage layer. Another way of charging the storage layer consists in utilizing an electron tunnelling operation, which is assisted by an electric field, through the gate dielectric.

The electron tunnelling operation, assisted by an electric field, out of the storage layer through the gate dielectric to the channel region or to one of the source/drain regions can be utilized to discharge the storage layer. By way of example, by applying a voltage of 5 V to the source region and a voltage of −8 V to the second gate electrode. To detect the charge state of the storage layer contained in the memory cell during a read operation in the memory device, a defined read voltage is applied to the second gate electrode, and a voltage is applied between the source region and the drain region to generate a lateral field. The level of the drain current, above a threshold voltage, is approximately linearly dependent on the level of the voltage at the second gate electrode. The drain current is approximately absent beneath the threshold voltage. If the storage layer is charged, for example, with negative charge carriers and therefore has a negative electrical potential, the threshold voltage shifts toward a higher voltage at the second gate electrode. To enable a measurable drain current to flow, a higher voltage is applied to the second gate electrode. With a suitable constant read voltage at the second gate electrode, the drain current flows as a function of the charge state of the storage layer; in the charged state of the storage layer, the drain current is virtually absent, that is, can be allocated the logic value zero, and in the discharged state the drain current has a finite value and can be allocated the logic value one. A detailed description of the above processes is to be found in the book entitled Flash Memories, edited by P. Cappelletti, C. Golla, P. Olivo, E. Zanoni, Kluwer Academic Publishers, 53-58 (1999).

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a diagrammatic cross section through a memory cell corresponding to the prior art.

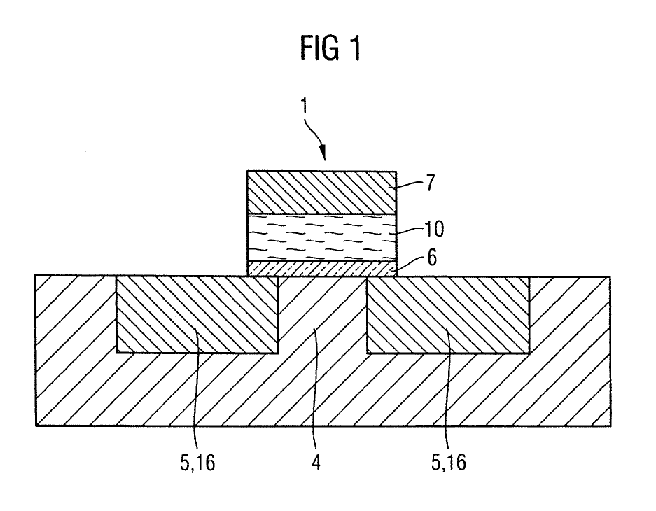

FIG. 2 illustrates a diagrammatic cross section through a first exemplary embodiment of a memory cell according to the invention.

FIG. 3 illustrates a diagrammatic cross section through a second exemplary embodiment of a memory cell according to the invention.

FIG. 4 illustrates a plan view of a diagrammatic excerpt from a memory device according to one embodiment of the invention.

FIG. 5 illustrates current/voltage characteristic curves of a field-effect transistor with organic storage layer.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

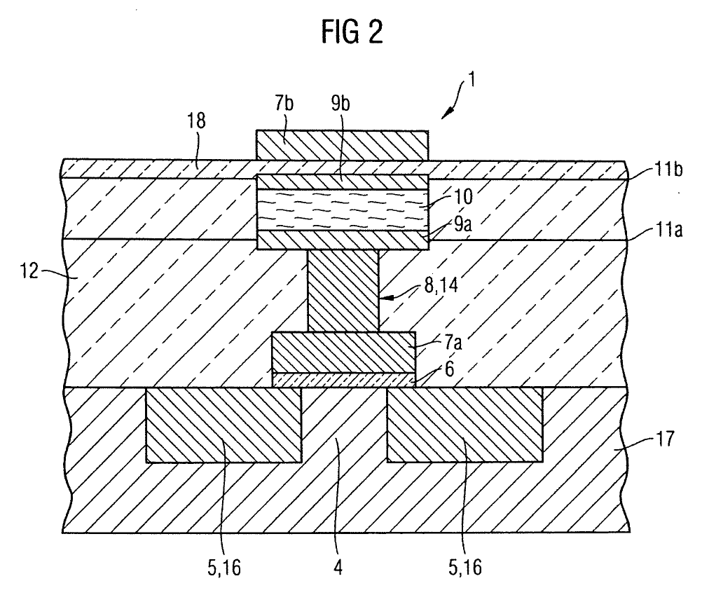

To fabricate a memory cell 1 illustrated in FIG. 2, in which digital information is stored in a temperature-sensitive organic storage layer 10, two source/drain regions 5 as doped regions, which are spaced apart from one another by a channel region 4, are provided in a semiconductor substrate 17. A gate dielectric 6 is arranged substantially above the channel region 4, and a first gate electrode 7a is arranged on the gate dielectric 6. The organic storage layer 10 is provided above the first gate electrode 7a between a first metal level 11a and a second metal level 11b. On account of the fact that the organic storage layer 10 is arranged above the polycrystalline or monocrystalline semiconductor structures, that is, the structures which are provided in the semiconductor substrate 17 or consist of a semiconductor substrate 17, it is possible for processing of the semiconductor structures to be concluded prior to the application of the organic storage layer 10. Since temperatures of up to 1100 degrees Celsuis are employed in the processing of the semiconductor structures and the organic storage layer 10 is damaged at such temperatures, applying the organic storage layer 10 at a later time allows the thermal stressing of the organic storage layer 10 to be reduced. A conductive connection 8 connects the organic storage layer 10 to the first gate electrode 7a, and this organic storage layer 10 can be charged by electrons which pass from the channel region 4 through the gate dielectric 6 into the first gate electrode 7a. The conductive connection is provided in the form of a metal-filled contact hole 14 which is introduced into an insulation layer 12. The organic storage layer 10 has been introduced into a hole between two metal levels 11a, b and is arranged between a first and a second electrode 9a, b. The second gate electrode 7b, which is separated from the second electrode 9b by an insulator layer 18, is located above the second electrode. The second gate electrode 7b is used to drive a field-effect transistor comprising the elements described.

FIG. 2 reveals the elements of the field-effect transistor with the organic storage layer 10 contained in the memory cell 1. The source/drain regions 5, which are spaced apart from one another by a channel region 4, are located in a semiconductor substrate 17. A gate dielectric 6 is arranged above the channel region, and a first gate electrode 7a is arranged on the gate dielectric. Two metal levels 11a, b, in which the electrodes 9a, b are marked, can be seen. The organic storage layer 10 is located between the electrodes 9a, b. The conductive connection 8 between the first electrode 9a and the first gate electrode 7a is illustrated in the form of a metal-filled contact hole 14 in the insulation layer 12. An insulator layer 18 is provided on the second electrode 9b, and the second gate electrode 7b is provided on the insulator layer.

To further reduce the thermal stressing on the organic storage layer 10, it is expedient for the application of the storage layer 10 to be shifted closer to the end of an overall process sequence used to fabricate the memory device 2. This is done, for example, by arranging the storage layer 10 between two higher metal levels 11 which are processed last. The conductive connection 8 of the first electrode 9a to the first gate electrode 7a is produced by contact holes 14, which have been introduced into insulation layers 12, have been stacked on top of one another, have been filled with metal and allow contact through metal levels 11 below.

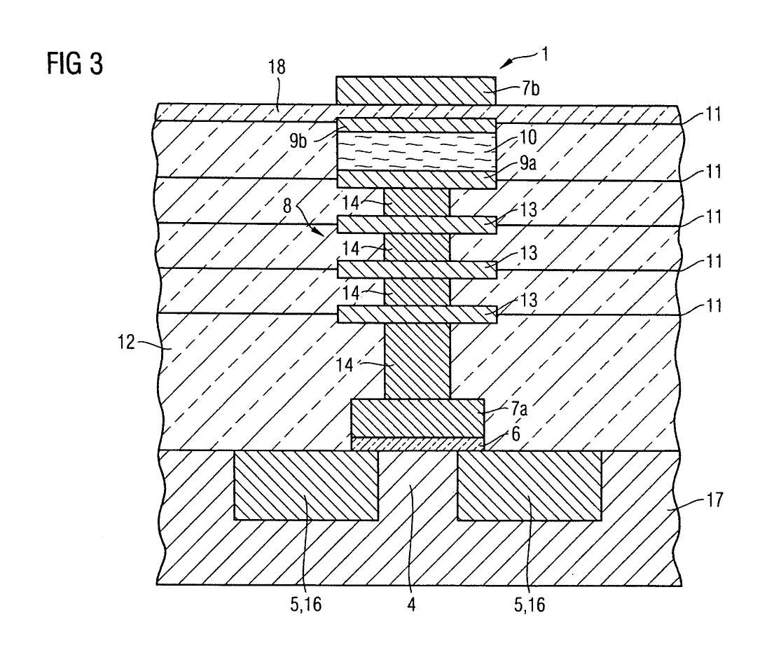

The exemplary embodiment of the memory cell 1 illustrated in FIG. 3 differs from the exemplary embodiment of the memory cell 1 illustrated in FIG. 2 by virtue of the form of its conductive connection 8. The organic layer 10 is located between two higher metal levels 11. The conductive connection 8 comprises contact holes 14 which are stacked on top of one another, have been filled with metal, have been introduced into the insulation layers 12 provided between the metal levels 11 and produce contact through a plurality of metal levels 11 which include interconnects 13 and contact holes 14.

To fabricate a memory device 2 from the memory cells 1, the memory cells 1 are, for example, arranged in rows and columns. Memory cells 1 which are in each case adjacent in rows and columns are connected to one another by interconnects 13 which are arranged perpendicular to one another and lie above one another at crossing points 15. One interconnect 13 connects source/drain regions 5 of memory cells 1 which are adjacent in a row and is also referred to as a bit line 13b. The other interconnect 13 connects the second gate electrodes 7b of the memory cells 1 which are adjacent in the columns and is also referred to as an addressing line 13a. Both bit line 13b and addressing line 13a are in each case formed in a respective metal level 11. Since the bit line 13b is supposed to make contact with the respective source/drain region 5 in each memory cell 1, and contacts would take up space in the memory cell 1, to save on surface area, the source/drain regions 5 of the memory cells 1 are electrically conductively connected to one another by doped regions 16 in the semiconductor substrate 17. A conductive connection 8 to the bit line 13b is only provided every 8 or 16 memory cells 1, for example.

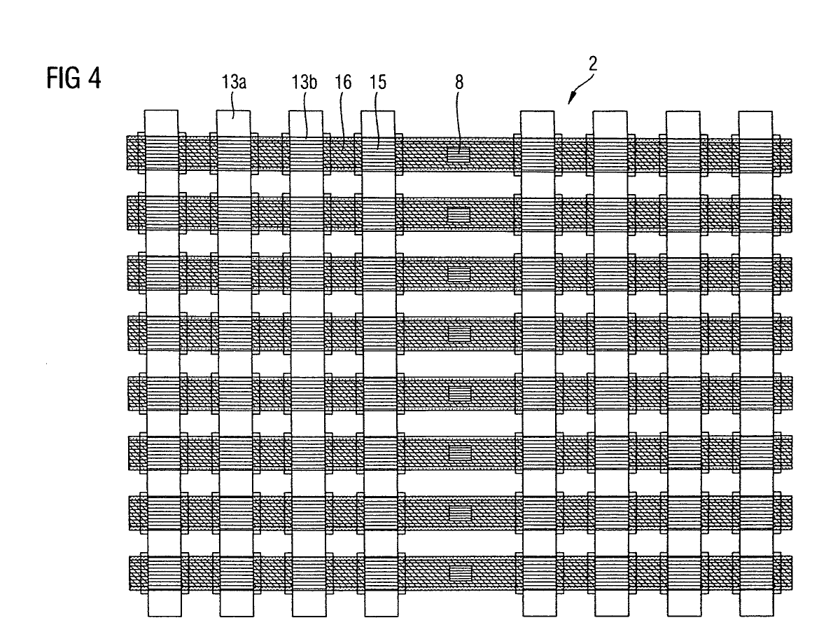

An excerpt from the memory device 2 can be seen in FIG. 4. This figure illustrates bit lines 13b and addressing lines 13a arranged in a crossed pattern. The memory cells 1 arranged in rows and columns are located at the crossing points 15. The doped regions 16, which are formed as lines and connect the source/drain regions 5 of memory cells 1 that are adjacent in a row to one another, can be seen in the excerpt, as can the conductive connection 8 to the bit line 13b.

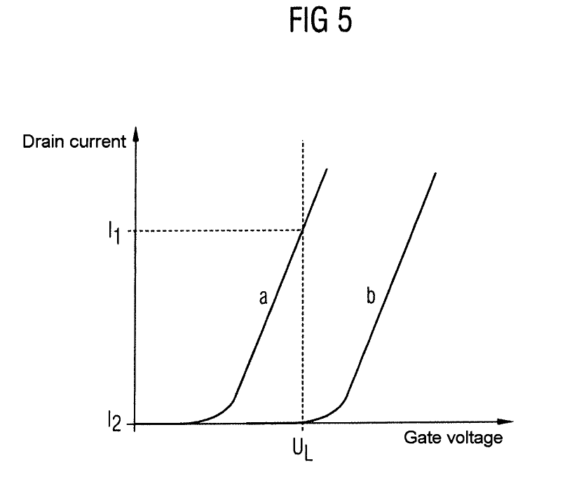

The current/voltage characteristic curves of a memory cell 1 with organic storage layer 10 illustrated in FIG. 5 have already been explained in more detail in the introduction to the description.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1-20. (canceled)

21. A method for fabricating a memory device, including semiconductor structures with memory cells in which digital information is stored in a storage layer, the method comprising:
forming two source/drain regions which are spaced apart from one another by a channel region in a semiconductor substrate;
producing a gate dielectric on a substrate surface of the semiconductor substrate above the channel region;
arranging a first gate electrode on the gate dielectric;
forming the storage layer as an organic layer;
concluding processing of the semiconductor structures prior to application of the storage layer;
providing a conductive connection between the storage layer and the first gate electrode; and
arranging an insulator layer above the storage layer and arranging a second gate electrode on the insulator layer.

22. The method of claim 21, further comprising arranging the storage layer between a first and a second electrode.

23. The method as claimed in claim 22, further comprising forming the first electrode by a portion of the conductive connection.

24. The method of claim 22, further comprising providing one metal from the group comprising aluminum, tungsten, and copper for the first and second electrodes.

25. The method of claim 22, further comprising providing one precious metal from the group comprising Pt, Au, and Ag for the first and second electrodes.

26. The method of claim 22, further comprising:
forming the first electrode in a first metal level and the second electrode in a second metal level; and
producing the conductive connection between the first gate electrode and the first electrode by filling a contact hole with conductive material.

27. The method of claim 22, further comprising:
forming each of the first and second electrodes in a metal level which is in each case processed later in the process sequence; and
producing the conductive connection between the first electrode and the first gate electrode by contact holes arranged above one another and filled with conductive material.

28. The method of claim 21, wherein the organic layer is provided having porphyrin molecules.

29. The method of claim 21, wherein:
to produce source and drain lines, the source/drain regions of memory cells arranged in rows which are respectively adjacent within a row are electrically conductively connected to one another by doped regions provided in the semiconductor substrate; and
after a plurality of source/drain regions which have been electrically conductively connected to one another by doped regions in the semiconductor substrate, conductive connections to interconnects, which are formed in a metal level and connect the source/drain regions of memory cells, are arranged.

30. A memory cell comprising:
a storage layer that stores a digital information item;
two source/drain regions that are formed in a semiconductor substrate and that are spaced apart from one another by a channel region;
a gate dielectric arranged on a substrate surface of the semiconductor substrate above the channel region;
a first gate electrode arranged on the gate dielectric;
a conductive connection between the storage layer and the first gate electrode;
an insulator layer arranged above the storage layer, and a second gate electrode arranged on the insulator layer;
wherein the storage layer is formed as an organic layer; and
wherein the storage layer is arranged on the first gate electrode or at a distance from the first gate electrode.

31. The memory cell of claim 30, wherein the storage layer is arranged between a first and a second electrode.

32. The memory cell of claim 31, wherein the first electrode is formed by a portion of the conductive connection.

33. The memory cell of claim 31, wherein the first and second electrodes consist of one of the group of metals comprising aluminum, tungsten, and copper.

34. The memory cell of claims 31, wherein the first and second electrodes consist of one of the group of precious metals comprising Pt, Au, and Ag.

35. The memory cell of claim 31, wherein:
the first electrode is formed in a first metal level and the second electrode is formed in a second metal level; and
the conductive connection between the first gate electrode and the first electrode is provided by a contact hole filled with conductive material.

36. The memory cell of claim 31, wherein:
the first and second electrodes are each formed in a metal level which is in each case further away from the first gate electrode than the first or the second metal level; and
the conductive connection between the first electrode and the first gate electrode is formed by contact holes which have been introduced into insulation layers, are arranged above one another and have been filled with conductive material.

37. The memory cell of claim 30, wherein the organic storage layer contains porphyrin molecules.

38. A memory device comprising memory cells arranged in rows and semiconductor structures, and which store a digital information item, wherein the memory device includes memory cells comprising:
a storage layer that stores a digital information item;
two source/drain regions that are formed in a semiconductor substrate and that are spaced apart from one another by a channel region;
a gate dielectric arranged on a substrate surface of the semiconductor substrate above the channel region;
a first gate electrode arranged on the gate dielectric;
a conductive connection between the storage layer and the first gate electrode;
an insulator layer arranged above the storage layer, and a second gate electrode arranged on the insulator layer;
wherein the storage layer is formed as an organic layer; and
wherein the storage layer is arranged on the first gate electrode or at a distance from the first gate electrode.

39. The memory device of claim 18, wherein:
to provide source and drain lines, source/drain regions of memory cells which are respectively adjacent in a row are electrically conductively connected to one another by doped regions provided in the semiconductor substrate; and
after a predetermined number of source/drain regions which have been electrically conductively connected to one another by doped regions in the semiconductor substrate, conductive connections to interconnects, which are formed in a metal level and connect the source/drain regions of memory cells, are arranged.

40. A method for operating a memory device having:
a storage layer that stores a digital information item;
two source/drain regions that are formed in a semiconductor substrate and that are spaced apart from one another by a channel region;
a gate dielectric arranged on a substrate surface of the semiconductor substrate above the channel region;
a first gate electrode arranged on the gate dielectric;
a conductive connection between the storage layer and the first gate electrode;
an insulator layer arranged above the storage layer, and a second gate electrode arranged on the insulator layer;
wherein the storage layer is formed as an organic layer; and
wherein the storage layer is arranged on the first gate electrode or at a distance from the first gate electrode, the method comprising:
charging the respective storage layers of selected memory cells by means of an electron tunneling operation through the gate dielectric as a result of voltages being applied to the source/drain regions and the second gate electrode in order to program the memory device;
discharging the charged storage layers by means of an electron tunneling operation to the channel region or to the source/drain region as a result of an erase voltage, which differs from the voltage applied during programming, being applied to the second gate electrode in order to erase the programming; and
detecting the strength of a drain current as a function of a charge state of the storage layer in order to read the programmed memory device.
